(19) United States
(12) Patent Application Publication
(10) Pub. No.: US 2015/0070072 A1
(43) Pub. Date: Mar. 12, 2015

(54) HARMONIC MIXER

(71) Applicants: DENSO CORPORATION, Kariya-city (JP); WASEDA UNIVERSITY, Tokyo (JP)

(72) Inventors: Toshihiko YOSHIMASU, Kitakyushu-city (JP); Takayuki SHIBATA, Nisshin-city (JP)

(21) Appl. No.: 14/476,978

(22) Filed: Sep. 4, 2014

(30) Foreign Application Priority Data
Sep. 6, 2013 (JP) 2013-185047

(51) Int. Cl. H03D 7/14

(52) U.S. Cl. CPC H03D 7/1458
USPC 327/356

(57) ABSTRACT

A harmonic mixer includes first through third field effect transistors. A gate electrode of the first field effect transistor is supplied with a positive-phase signal of a first signal. A gate electrode of the second field effect transistor is supplied with a negative-phase signal of the first signal. A source electrode of the second field effect transistor is short-circuited with a source electrode of the first field effect transistor and is grounded. A source electrode of the third field effect transistor is connected to a terminal at which drain electrodes of the first field effect transistor and the second field effect transistor are short-circuited. A gate electrode of the third field effect transistor is supplied with a second signal. A drain electrode of the third field effect transistor outputs a signal.

### CROSS REFERENCE TO RELATED APPLICATIONS

The present application is based on and claims priority to Japanese Patent Application No. 2013-185047 filed on Sep. 6, 2013, the contents of which are incorporated in their entirety herein by reference.

### TECHNICAL FIELD

The present disclosure relates to a harmonic mixer.

### BACKGROUND

When a harmonic mixer receives and down-converts a radio-frequency (RF) signal of high frequency, the harmonic mixer down-converts by receiving a local oscillation (LO) differential signal and mixing the LO differential signal with the RF signal as described, for example, in WO01/001564 (US 2001/0005151 A1),

The inventors of the present application found that, in the configuration described in WO01/001534, a multiplication processing of a doubled signal of the LO signal (first signal) and the RF signal (second signal) may be insufficient, and a leakage signal becomes large. In the present disclosure, the doubled signal of the LO signal means a signal having a frequency twice as high as a frequency of the LO signal.

### SUMMARY

It is an object of the present disclosure to provide a harmonic mixer that can sufficiently perform a multiplication processing of a doubled signal of a first signal and a second signal and can restrict a leakage signal.

A harmonic mixer according to a first aspect of the present disclosure includes first through third field effect transistors. A gate electrode of the first field effect transistor is supplied with a positive-phase signal of a first signal. A gate electrode of the second field effect transistor is supplied with a negative-phase signal of the first signal. A source electrode of the second field effect transistor is short-circuited with a source electrode of the first field effect transistor and is grounded. A source electrode of the third field effect transistor is connected to a terminal at which drain electrodes of the first field effect transistor and the second field effect transistor are short-circuited. A gate electrode of the third field effect transistor is supplied with a second signal. A drain electrode of the third field effect transistor outputs a signal.

The harmonic mixer according to the first aspect can sufficiently perform a multiplication processing of a doubled signal of the first signal and the second signal and can restrict a leakage signal.

A harmonic mixer according to a second aspect of the present disclosure includes first through third bipolar transistor. A base electrode of the first bipolar transistor is supplied with a positive-phase signal of a first signal. A base electrode of the second bipolar transistor is supplied with a negative-phase signal of the first signal. An emitter electrode of the second bipolar transistor is short-circuited with an emitter electrode of the first bipolar transistor and is grounded. An emitter electrode of the third bipolar transistor is connected to a terminal at which collector electrodes of the first bipolar transistor and the second bipolar transistor are short-circuited. A base electrode of the third bipolar transistor is supplied with a second signal. A collector electrode of the third bipolar transistor outputs a signal.

The harmonic mixer according to the second aspect can sufficiently perform a multiplication processing of a doubled signal of the first signal and the second signal and can restrict a leakage signal.

A harmonic mixer according to a third aspect of the present disclosure includes first and second n-type field effect transistors and a p-type field effect transistor. A gate electrode of the first n-type filed effect transistor is supplied with a positive-phase signal of a first signal. A gate electrode of the second n-type field effect transistor is supplied with a negative-phase signal of the first signal. A source electrode of the second n-type field effect transistor is short-circuited with a source electrode of the first n-type field effect transistor and is grounded. A drain electrode of the p-type field effect transistor is connected to a terminal at which drain electrodes of the first n-type field effect transistor and the second n-type field effect transistor are short-circuited. A gate electrode of the p-type field effect transistor is supplied with a second signal. The drain electrode of the p-type field effect transistor outputs a signal.

The harmonic mixer according to the third aspect can sufficiently perform a multiplication processing of a doubled signal of the first signal and the second signal and can restrict a leakage signal.

A harmonic mixer according to a fourth aspect of the present disclosure includes first through sixth field effect transistors. A gate electrode of the first field effect transistor is supplied with a positive-phase signal of a first signal. A gate electrode of the second field effect transistor is supplied with a negative-phase signal of the first signal. A source electrode of the second field effect transistor is short-circuited with a source electrode of the first field effect transistor and is grounded. A source electrode of the third field effect transistor is connected to a terminal at which drain electrodes of the first field transistor and the second field transistor are short-circuited. A gate electrode of the third field effect transistor is supplied with a positive-phase signal of a second signal. A drain electrode of the third field effect transistor outputs a negative-phase signal of an output signal.

A gate electrode of the fourth field effect transistor is supplied with the positive-phase signal of the first signal. A gate electrode of the fifth field effect transistor is supplied with the negative-phase signal of the first signal. A source electrode of the fifth filed effect transistor is short-circuited with a source electrode of the fourth field effect transistor and is grounded. A source electrode of the sixth field effect transistor is connected to a terminal at which drain electrodes of the fourth field effect transistor and the fifth field effect transistors are short-circuited. A gate electrode of the sixth field effect transistor is supplied with a negative-phase signal of the second signal. A drain electrode of the sixth field effect transistor outputs a positive-phase signal of the output signal.

The harmonic mixer according to the fourth aspect can sufficiently perform a multiplication processing of a doubled signal of the first signal and the second signal and can restrict a leakage signal.

### BRIEF DESCRIPTION OF THE DRAWINGS

Additional objects and advantages of the present disclosure will be more readily apparent from the following detailed description when taken together with the accompanying drawings. In the drawings:

FIG. 1 is a circuit diagram illustrating a harmonic mixer according to a first embodiment of the present disclosure;

FIG. 2 is a diagram illustrating a simulation result of FFT waveforms of signals generated at an output terminal of the harmonic mixer according to the first embodiment;

FIG. 3A is a diagram illustrating a simulation result of a time scale waveform of the signal generated at the output terminal according to the first embodiment, and FIG. 3B is an enlarged view of a part D of the time scale waveform illustrated in FIG. 3A;

FIG. 4 is a circuit diagram illustrating a harmonic mixer according to a comparative example;

FIG. 5 is a diagram illustrating a simulation result of FFT waveforms of signals generated at an output terminal of the harmonic mixer according to the comparative example;

FIG. 6A is a diagram illustrating a simulation result of a time scale waveform of the signal generated at the output terminal according to the comparative example, and FIG. 6B is an enlarged view of a part D of the time scale waveform illustrated in FIG. 6A;

FIG. 7 is a circuit diagram illustrating a harmonic mixer according to a second embodiment of the present disclosure;

FIG. 8 is a circuit diagram illustrating a harmonic mixer according to a third embodiment of the present disclosure;

FIG. 9 is a circuit diagram illustrating a harmonic mixer according to a fourth embodiment of the present disclosure; and

FIG. 10 is a circuit diagram illustrating a harmonic mixer according to a fifth embodiment of the present disclosure.

### DETAILED DESCRIPTION

Harmonic mixers according to embodiments of the present disclosure will be described with reference to the drawings. In each of the embodiments, identical reference symbols are given to same or similar portions, description about the same or similar portions will be omitted as necessary, and a characterizing portion will be mainly described.

### First Embodiment

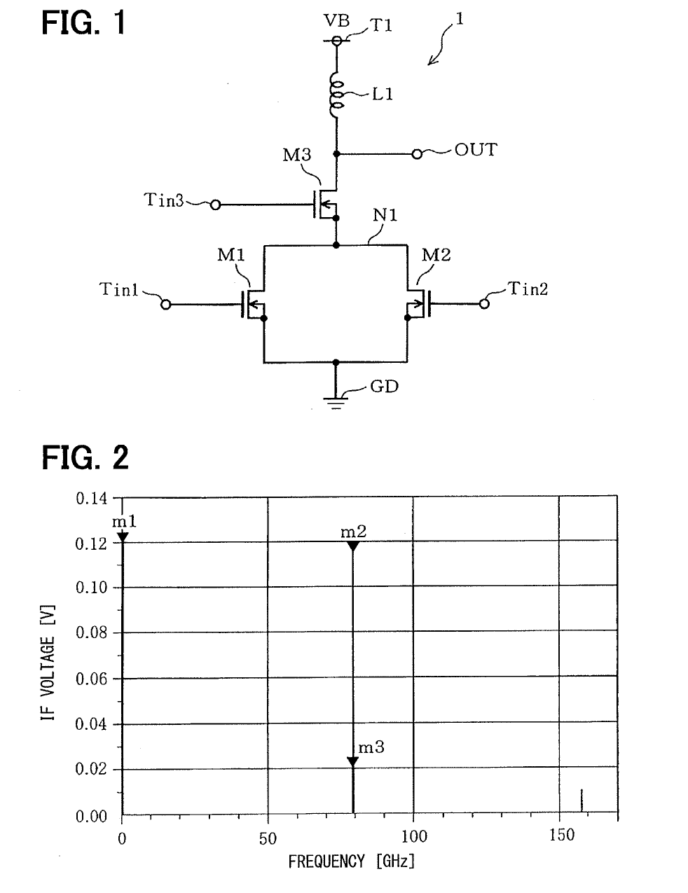

A harmonic mixer 1 according to a first embodiment of the present disclosure will be described with reference to FIG. 1. The harmonic mixer 1 includes transistors M1-M3 and an inductor L1. The transistors M1-M3 are examples of first through third field effect transistors. Each of the transistors M1-M3 is formed of an N-channel MOSFET.

The N-channel MOSFET is used because, when an FET is formed using semiconductor such as silicon (Si), a high performance can be maintained in characteristics such as cut-off frequency, and the FET can be suitably used for a high-frequency circuit. When the inductor L1 is formed, for example, in a semiconductor substrate, a metal wiring is formed so as to have a spiral shape.

Drains of the transistors M1 and M2 are commonly connected to a drain common connection node, and sources of the transistors M1 and M2 are commonly connected to a source common connection node. The source common connection node is connected to a ground GD. The drain common connection node of the transistors M1 and M2 is also referred to a node N1. Between a terminal T1 of a power voltage BV and the ground terminal GD, the inductor L1, a drain and a source of the transistor M3, the drain common connection node and the source common connection node of the transistors M1 and M2 are connected in series. A difference from the harmonic converter described in WO01/001534 is that a source of the transistor M3 is connected to the drains the transistors M1 and M2.

A gate of the transistor M1 is connected to an input terminal Tin1. The input terminal Tin1 is supplied with a positive-phase signal of a local oscillation (LO) differential signal. The LO differential signal is an example of a first signal. A gate of the transistor M2 is connected to an input terminal Tin2. The input terminal Tin2 is supplied with a negative-phase signal of the LO differential signal.

A gate of the transistor M3 is connected to an input terminal Tin3. The input terminal Tin3 is supplied with a radio frequency (RF) signal. The RF signal is an example of a second signal. A common connection node of the inductor L1 and the drain of the transistor M3 is connected to an output terminal OUT.

In the circuit configuration illustrated in FIG. 1, a direct-current bias voltage between the gate and the source of each of the transistors M1, M2 is set to a value near a threshold voltage of each of the transistors M1, M2. Thus, each of the transistors M1, M2 is ON for a half period during which a gate signal applied to each of the transistors M1, M2 is positive. The differential signal is complimentarily applied to the gates of the transistors M1, M2. Thus, when one of the transistors (e.g., the transistor M1) is ON, the other transistor (e.g., the transistor M2) is OFF.

At this time, a signal having a frequency (2×f_{LO}) twice as high as a frequency of the LO signal is generated. Hereafter, the signal is referred to as a doubled signal of the LO signal. The doubled signal of the LO signal is supplied to the source of the transistor M3, which is an amplifier circuit for the RF signal. On the other hand, the gate of the transistor M3 is supplied with the RF signal. Thus, between the gate and the source of the transistor M3, the doubled signal of the LO signal and the RF signal are effectively multiplied.

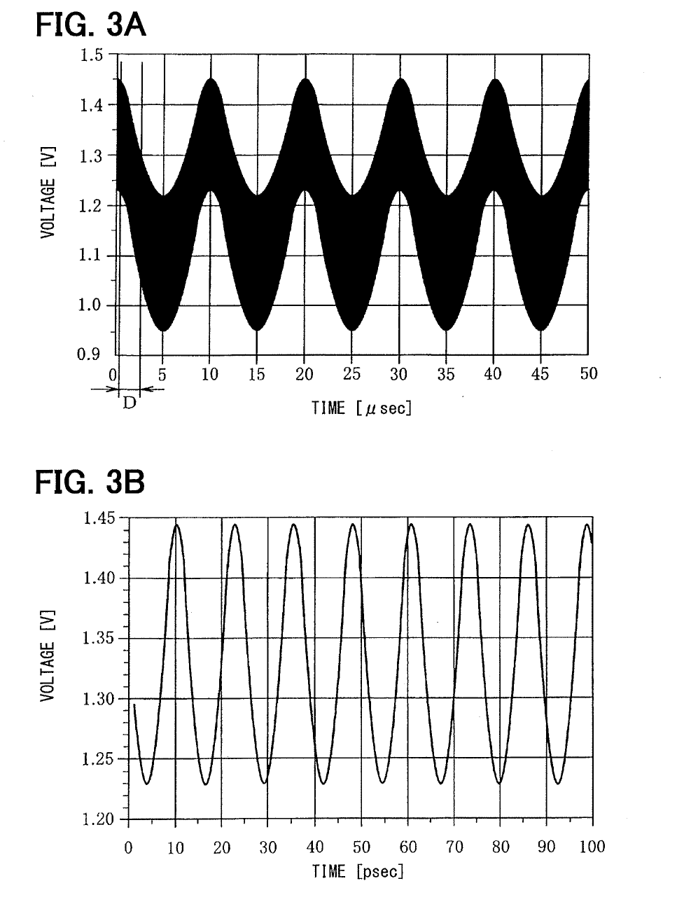

An IF signal generated by a multiplication result becomes a drain current of the transistor M3 and is supplied to the output terminal. Simulation results of circuit characteristics of the harmonic mixer 1 are illustrated in FIG. 2, FIG. 3A, and FIG. 3B. FIG. 2 is a diagram illustrating the simulation result of FFT waveforms of signals generated at the output terminal OUT. In FIG. 2, a horizontal axis shows a frequency and a vertical axis shows a magnitude of a detection voltage. FIG. 3A is a diagram illustrating the simulation result of a time scale waveform of the signal generated at the output terminal OUT, and FIG. 3B is an enlarged view of a part D of the time scale waveform illustrated in FIG. 3A. In FIG. 3A and FIG. B, a horizontal axis shows a time, and a vertical axis shows a voltage value.

In the simulation, the frequency of the RE signal is set to 79.0001 GHz (see m2 in FIG. 2). In addition, the frequency of the LO signal is set to 39.5 GHz so that the frequency of the doubled signal of the LO signal is set to 79 GHz (m3 in FIG. 2). The simulation is performed on condition that the LO signal supplied to the input terminals Tint Tin2 has an output power of 1 mW and has a signal source output impedance of 50 Ω, and the RF signal supplied to the input terminal Tin3 has an output power of 0.01 mW and has a signal source output impedance of 50 Ω.

In the FFT waveform illustrated in FIG. 2, the RF signal m2 has a magnitude of 0.11523, the doubled signal of the LO signal m3 has a magnitude of 0.02047, and a mixed signal ml has a magnitude of 0.0120.

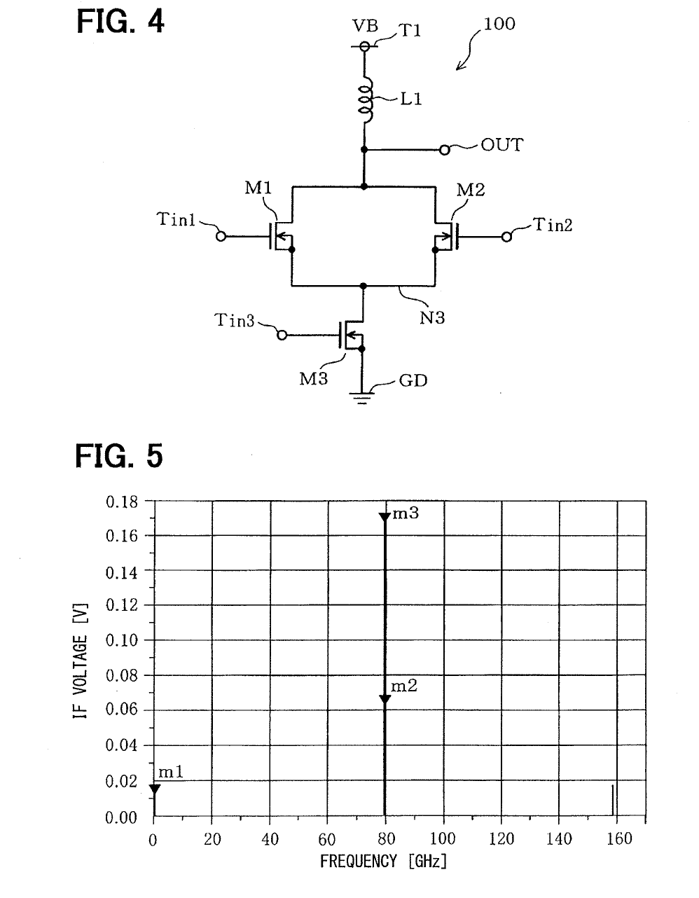

Next, a circuit configuration of a harmonic mixer 100 according to a comparative example will be described with reference to FIG. 4. The harmonic mixer 100 has a circuit configuration similar to the circuit configuration described in WO01/001564. The harmonic mixer 100 includes transistors M1-M3 and an inductor L1 connected as illustrated in FIG. 4. Drains of the transistors M1 and M2 are commonly connected to a drain common connection node N2, and sources of the transistors M1 and M2 are commonly connected to a source common connection node N3.

A drain and a source of the transistor M3 is connected between the source common connection node N3 of the transistors M1, M2 and a ground GD. Between the drain common connection node N2 of the transistors M1, M2 and a supply terminal T1 of a positive power supply voltage VB, an inductor L1 is connected. The drain common connection node N2 is set to an output terminal OUT. A gate of the transistor M3 is connected to an input terminal Tin3. The input terminal Tin3 is supplied with an RF signal. Gates of the transistors M1, M2 are respectively connected to input terminals Tin1, Tin2. The input terminals Tin1, Tin2 are supplied with the LO differential signal. Specifically, the input terminal Tin1 is supplied with a positive-phase signal of the LO differential signal, and the input terminal Tin2 is supplied with a negative-phase signal of the LO differential signal. Then, at the drain of the transistor M1, a mixed wave of the positive-phase signal of the LO signal and a harmonic wave thereof, and the RF signal is generated. In contrast, at the drain of the transistor M2, a mixed wave of the negative-phase signal of the LO signal and a harmonic wave thereof, and the RF signal is generated.

Next, analysis results of the harmonic mixer 1 according to the present embodiment and the harmonic mixer 100 according to the comparative example will be described. Both in the harmonic mixer 1 illustrated in FIG. 1 and the harmonic mixer 100 illustrated in FIG. 4, fundamental wave signals after down-conversion (e.g., frequency f=f_{RF}−f_{LO}) have opposite-phase relation to each other at the output terminal OUT. Thus, the fundamental signals after down-conversion are not output in principle. In addition, mixed waves of the odd-numbered order harmonic waves of the LO signal (2n−1) F_{LO} (where, n is an integral number equal to or greater than 1) and the RF signal also have opposite-phase relation to each other and are not supplied to the output terminal OUT in principle.

As a result, output signals of the output terminal OUT having the same phase are generated by mixed waves of the even-numbered order harmonic waves of the LO signal (2n·f_{LO}) and the RF signal, and the output signals have frequencies of 2n·f_{LO}±m·f_{RF} (where m is an integral number equal to or greater than 1).

The above-described phenomenon is expressed by the following equation (1).

$$cos ( {ω}_{RF} t ) \times cos ( 2 {ω}_{LO} t ) = \frac{1}{2} [ cos ( {ω}_{RF} - 2 {ω}_{LO} ) t ] + [ cos ( {ω}_{RF} + 2 {ω}_{LO} ) t ] \qquad ( 1 )$$

Thus, the IF signal (f_{RF}−2f_{LO}) can be generated by effectively multiplying the doubled signal of the LO signal and the RF signal.

Because the transistors M1, M2 are ON during a half period of the LO differential signal and are OFF during the other half period, the transistors M1, M2 generate the doubled signals of the LO signal. The transistor M3 amplifies the RF signal.

However, in the harmonic mixer 100 according to the comparative example, which is illustrated in FIG. 4, the RF signal amplified by the transistor M3 is not effectively mixed in the transistors M1, M2 and leaks to the output terminal 4, as confirmed by the inventors.

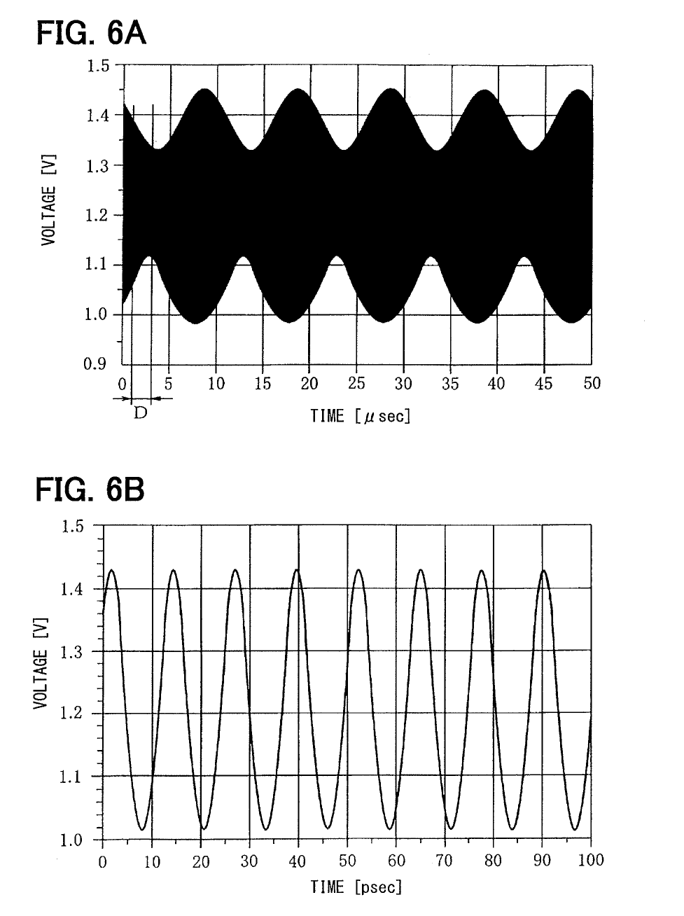

Simulation results using the harmonic mixer 100 illustrated in FIG. 4 will be described with reference to FIG. 5, FIG. 6A, and FIG. 6B. FIG. 5 is a diagram illustrating the simulation result of FFT waveforms of signals generated at the output terminal OUT. In FIG. 2, a horizontal axis shows a frequency and a vertical axis shows a magnitude of a detection voltage. FIG. 6A is a diagram illustrating the simulation result of a time scale waveform of the signal generated at the output terminal OUT, and FIG. 6B is an enlarged view of a part D of the time scale waveform illustrated in FIG. 6A.

In order to show on a scale similar to FIG. 2, the frequency of the RF signal is set to 79.0001 GHz (m2 in FIG. 5). In addition, the frequency of the LO signal is set to 39.5 GHz so that the frequency of the doubled signal of the LO signal is set to 79 GHz (m3 in FIG. 5). The simulation is performed on condition that the LO signal has an output power of 1 mW and has a signal source output impedance of 50 Ω, and the RF signal has an output power of 0.01 mW and has a signal source output impedance of 50 Ω.

In the FFT waveforms illustrated in FIG. 5, the RF signal m2 has a magnitude of 0.0624, the doubled signal of the LO signal m3 has a magnitude of 0.1675, and a mixed signal m1 has a magnitude of 0.012. The RF signal amplified by the transistor M3 and signals of doubled frequency (2×f_{LO}) generated by the transistors M1, M2 largely appear at the output terminal OUT. However, a necessary IF signal (100 kHz) is very small. Thus, in the harmonic mixer 100 illustrated in FIG. 4, the RF signal and the doubled signal are not mixed effectively.

When analyzed with time scale, as illustrated in FIG. 6A, an amplitude modulation waveform in which the frequency f_{RF} of the RF signal and the doubled frequency 2×f_{LO} the LO signal are simply added appears. In other words, a signal that appears at the output terminal OUT satisfies the following equation (2).

$$cos ( {ω}_{RF} t ) + cos ( {ω}_{2 LO} t ) = 2 [ cos ( \frac{( {ω}_{RF} - 2 {ω}_{LO} ) t}{2} ) \times cos ( \frac{( {ω}_{RF} + 2 {ω}_{LO} ) t}{2} ) ] \qquad ( 2 )$$

Thus, the waveform illustrated in FIG. 6A has an amplitude fluctuation by the influence of cos (ω_{RF}−2ω_{LO})t/2 in the equation (2). In addition, a voltage fluctuation in FIG. 6B is caused by cos (ω_{RF}+2ω_{LO})t/2. A harmonic mixer cannot obtain a sufficient amplitude of an IF signal unless an RF signal and a doubled signal of an LO signal are appropriately multiplied as expressed in the equation (2).

When the configuration of the harmonic mixer 1 according to the present embodiment is applied, as illustrated in the FFT waveforms in FIG. 2, the mixed IF signal m1 larger than the mixed IF signal m1 in FIG. 5 can be obtained. In addition, the doubled signal m3 of the LO signal is much smaller than the doubled signal m3 in FIG. 5. Thus, the leakage of the LO signal can be restricted. Accordingly, the harmonic mixer 1 according to the present embodiment can effectively perform the multiplication processing and can obtain the IF signal much larger than the IF signal obtained by the harmonic mixer 100 according to the comparative example.

FIG. 3A illustrates the simulation result of the time scale waveform of the signal generated at the output terminal OUT. As is obvious from FIG. 3A, the harmonic mixer 1 according to the present embodiment can obtain the IF signal component much larger than the IF signal component in FIG. GA.

As described above, the harmonic mixer 1 according to the present embodiment generates the signal having the frequency twice as high as the frequency of the LO signal and can effectively mix with the RF signal. Thus, the harmonic mixer 1 according to the present embodiment can obtain the IF signal output much larger than the IF signal output obtained by the harmonic mixer 100.

### Second Embodiment

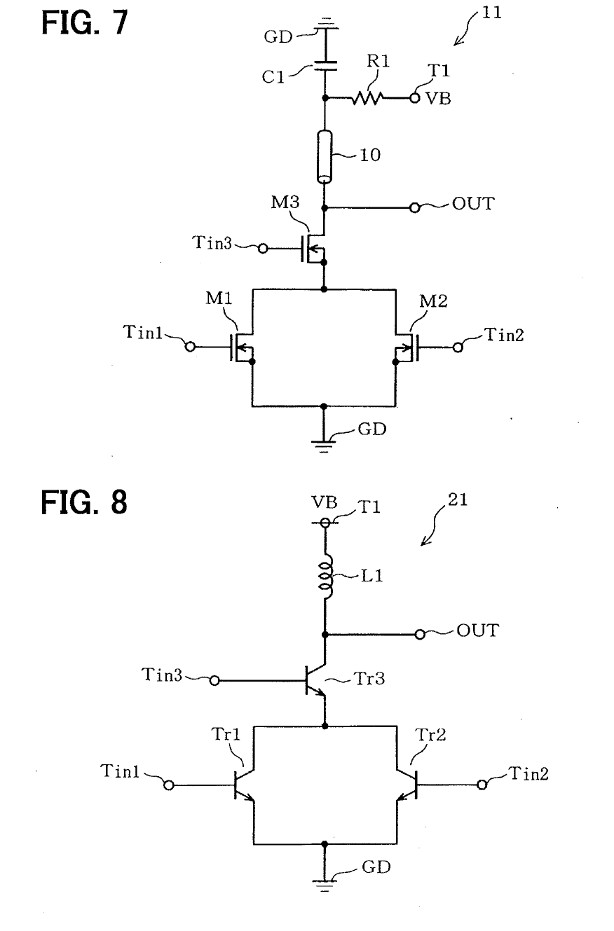

A harmonic mixer 11 according to a second embodiment of the present disclosure will be described with reference to FIG. 7. The harmonic mixer 11 according to the present embodiment is different from the harmonic mixer 1 according to the first embodiment in that a transmission line 10 having an inductivity is used instead of the inductor L1.

The inductor L1 described in the first embodiment is formed by forming the metal wiring on the semiconductor substrate into the spiral shape. The inductor L1 is practical in a low operation frequency region. However, in a high frequency region such as millimeter wave band, the inductor L1 may resonate based on a parasitic capacitance between the metal wirings even when the inductor L1 is formed in an integrated circuit. Therefore, in the present embodiment, an inductive load is formed using the transmission line 10. Accordingly, even when the operation frequency is high, the transmission line 10 can normally operate as the inductive load.

As illustrated in FIG. 7, a drain of a transistor M3 is connected to a ground GD via the transmission line 10 and a capacitor C1. The transmission line 10 can be formed of various lines such as a micro strip line or a coplanar line. A line length of the transmission line 10 is set to a predetermined length having inductivity at the operation frequency. The transmission line 10 can be formed by combining the above-described lines.

The capacitor C1 is set to a value (e.g., several pF) that can be regarded as a short circuit at a frequency of the LO signal (e.g., several tens of GHz) and can be regarded as a load resistance in an IF signal band. When formed in an integrated circuit, a capacitance between signal wires can be used for the capacitor Cl. To a common connection node of the capacitor C1 and the transmission line 10, a power supply voltage VB is supplied via a resistor R1. If an output impedance of the power supply voltage VB is appropriately set, the resistance R1 may be provided as necessary. The harmonic mixer 11 according to the present embodiment can have effects similar to the effects of the harmonic mixer 1 according to the first embodiment.

### Third Embodiment

A harmonic mixer 21 according to a third embodiment of the present disclosure will be described with reference to FIG. 8. The harmonic mixer 21 according to the present embodiment is different from the harmonic mixer 1 according to the first embodiment in that bipolar transistors Tr1-Tr3 are used instead of the MOS transistors M1-M3.

In other words, as illustrated in FIG. 8, base electrodes, collector electrodes, emitter electrodes in the transistors Tr1-Tr3 according to the present embodiment correspond to the gate electrodes, the drain electrodes, and the source electrodes of the transistors M1-M3 according to the first embodiment and are electrically connected in a manner similar to the first embodiment.

The transistors Tr1 and Tr2 are formed of npn bipolar transistors and are used as a pair of transistors that generate signals having a doubled frequency of an LO signal. The transistor Tr3 is also formed of an npn bipolar transistor and amplifies an RF signal. The harmonic mixer 21 according to the present embodiment can have effects similar to the effects of the harmonic mixer according to the first embodiment.

### Fourth Embodiment

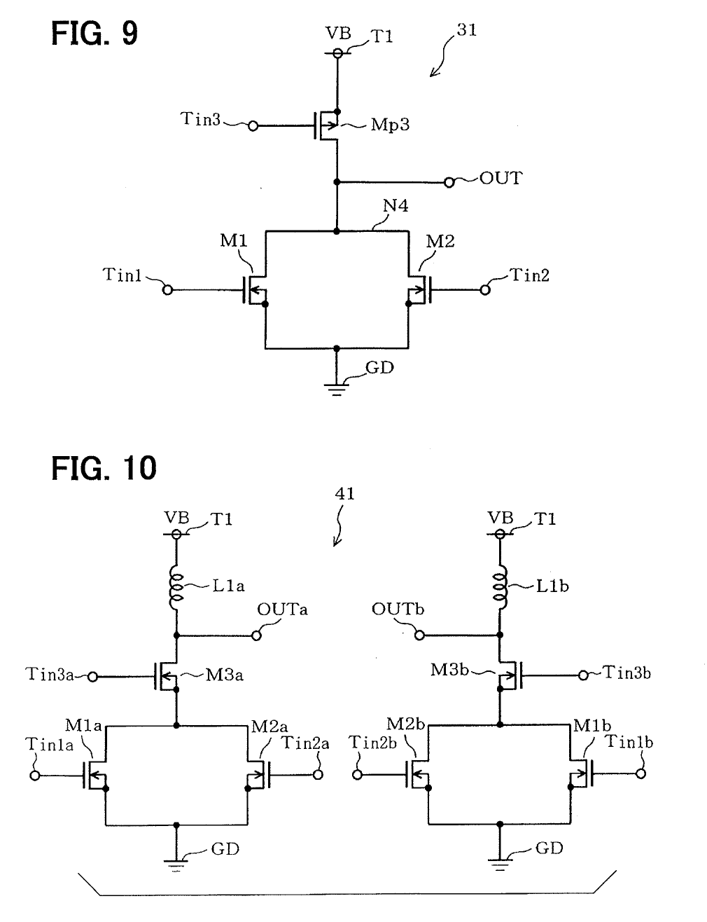

A harmonic mixer 31 according to a fourth embodiment of the present disclosure will be described with reference to FIG. 9. The harmonic mixer 31 according to the present embodiment is different from the harmonic mixer 1 according to the first embodiment in that (i) a transistor Mp3 for amplifying the RF signal is formed of a P-channel MOSFET instead of the N-channel MOS transistor M3, (ii) the output terminal OUT is a common connection node of a drain common connection node N4 of the transistors M1, M2 and the transistor Mp3, and (iii) the inductor Li for applying the power supply voltage VB is unnecessary.

When gates of the transistors M1, M2 are supplied with LO signals having opposite phases, the doubled signal of the LO signal can be generated similarly to the above-described embodiments. Because the transistor Mp3 is formed of the P-channel MOSFET, a power supply terminal T1 can be directly connected to a source of the transistor Mp3 without via a load such as an inductor.

An alternating-current potential of the power supply terminal T1 is grounded. Thus, when the output terminal OUT is acquired from the transistor Mp3, the harmonic mixer 31 can have effects similar to the above-described embodiments. The harmonic mixer 31 has principle of operation similarly to the harmonic mixer 1 according to the first embodiment. However, because the transistor Mp3 for amplifying the RF signal is formed of the P-channel MOSFET, a flicker noise (1/f noise) can be reduced compared with the N-channel MOSFET.

Thus, when the output signal is the IF signal having a low frequency, a noise power can be restricted. In addition, because the inductor L1 can be omitted, the harmonic mixer 31 can achieve downsizing and cost reduction compared with the above-described embodiments.

### Fifth Embodiment

A differential harmonic mixer 41 according to a fifth embodiment of the present disclosure will be described with reference to FIG. 10. The differential harmonic mixer 41 includes two harmonic mixers 1 illustrated in FIG. 1 and is formed as a double balanced mixer.

In the differential harmonic mixer 41, components in a first harmonic mixer are denoted with a letter “a,” and components in a second harmonic mixer are denoted with a letter “b”. Specifically, the harmonic mixer 41 includes transistors M1a-M3a and an inductor L1a, and further includes transistors M1b-M3b and an inductor L1b, which are respectively paired with the transistor M1a-M3a and the inductor L1a.

A gate of the transistor M3a in the first harmonic mixer is supplied with a positive-phase signal of the RF signal, and a gate of the transistor M3b in the other harmonic mixer is supplied with a negative-phase signal of the RF signal.

A gate electrode of the transistor M1a in the first harmonic mixer is connected to an input terminal Tin1a, a gate electrode of the transistor M1b in the second harmonic mixer is connected to an input terminal Tin1b, and both of the input terminals Tin1a, Tin1b are supplied with the negative-phase signal of the LO signal.

A gate electrode of the transistor M2a in the first harmonic mixer is connected to an input terminal Tin2a, a gate electrode of the transistor M2b in the second harmonic mixer is connected to an input terminal Tin2b, and both of the input terminals Tin2a, Tin2b are supplied with the positive-phase signal of the LO signal.

Then, the differential harmonic mixer 41 acquires a positive-phase signal from an output terminal OUTa in the first harmonic mixer and acquires a negative-phase signal from an output terminal OUTb in the second harmonic mixer.

The differential harmonic mixer 41 is effective when the RF signal is a differential signal. In the present embodiment, the differential harmonic mixer 41 is formed by combining two harmonic mixers 1 illustrated in FIG. 1. In another embodiment, a differential harmonic mixer may be formed by combining two harmonic mixers 11 illustrated in FIG. 7 and described in the second embodiment. In another embodiment, a differential harmonic mixer may be formed by combining two harmonic mixers 21 illustrated in FIG. 8 and described in the third embodiment. In another embodiment, a differential harmonic mixer may be formed by combining two harmonic mixers 31 illustrated in FIG. 9 and described in the fourth embodiment. Similar effects to the above-described embodiments can be achieved.

### Other Embodiments

Although the present invention has been fully described in connection with the exemplary embodiments thereof with reference to the accompanying drawings, it is to be noted that various changes and modifications will become apparent to those skilled in the art.

In the circuit configurations described in the first through fifth embodiments, an impedance matching circuit is not provided at the input terminal of the RF signal, the input terminal of the LO signal, and the output terminal of the IF signal. However, an impedance matching circuit may be provided as necessary in view of a connection with an external circuit.

For example, if an impedance matching is necessary when the transistors M1-M3 are connected with a signal source (not illustrated) or when the output terminal of the IF signal is connected with an external terminal (not illustrated), a matching may be performed appropriately using an inductor component and a capacitance component (e.g., transmission line).

In the first through fifth embodiments, the down-conversion processing in which the doubled signal of the LO signal (the first signal) and the RF signal (the second signal) are mixed and the IF signal is output has been described. A harmonic mixer according to another embodiment may be applied to an up converter in which an IF signal (a second signal) having a low frequency is applied to a gate of a transistor M3, an LO signal (a first signal) is applied to gates of transistors M1, M2, and a doubled signal of the LO signal and the IF signal are mixed to output an RF signal.

What is claimed is:

1. A harmonic mixer comprising:
a first field effect transistor whose gate electrode is supplied with a positive-phase signal of a first signal;
a second field effect transistor whose gate electrode is supplied with a negative-phase signal of the first signal, and whose source electrode is short-circuited with a source electrode of the first field effect transistor and is grounded; and
a third field effect transistor whose source electrode is connected to a terminal at which drain electrodes of the first field effect transistor and the second field effect transistor are short-circuited, whose gate electrode is supplied with a second signal, and whose drain electrode outputs a signal

2. A harmonic mixer comprising:
a first bipolar transistor whose base electrode is supplied with a positive-phase signal of a first signal;
a second bipolar transistor whose base electrode is supplied with a negative-phase signal of the first signal, and whose emitter electrode is short-circuited with an emitter electrode of the first bipolar transistor and is grounded; and
a third bipolar transistor whose emitter electrode is connected to a terminal at which collector electrodes of the first bipolar transistor and the second bipolar transistor are short-circuited, whose base electrode is supplied with a second signal, and whose collector electrode outputs a signal.

3. A harmonic mixer comprising:
a first n-type field effect transistor whose gate electrode is supplied with a positive-phase signal of a first signal;
a second n-type field effect transistor whose gate electrode is supplied with a negative-phase signal of the first signal and whose source electrode is short-circuited with a source electrode of the first n-type field effect transistor and is grounded; and
a p-type field effect transistor whose drain electrode is connected to a terminal at which drain electrodes of the first n-type field effect transistor and the second n-type field effect transistor are short-circuited, whose gate electrode is supplied with a second signal, and whose drain electrode outputs a signal.

4. A harmonic mixer comprising:
a first field effect transistor whose gate electrode is supplied with a positive-phase signal of a first signal;
a second field effect transistor whose gate electrode is supplied with a negative-phase signal of the first signal, and whose source electrode is short-circuited with a source electrode of the first field effect transistor and is grounded;
a third field effect transistor whose source electrode is connected to a terminal at which drain electrodes of the first field transistor and the second field transistor are short-circuited, whose gate electrode is supplied with a positive-phase signal of a second signal, and whose drain electrode outputs a negative-phase signal of an output signal;
a fourth field effect transistor whose gate electrode is supplied with the positive-phase signal of the first signal;
a fifth field effect transistor whose gate electrode is supplied with the negative-phase signal of the first signal, and whose source electrode is short-circuited with a source electrode of the fourth field effect transistor and is grounded; and
a sixth field effect transistor whose source electrode is connected to a terminal at which drain electrodes of the fourth field effect transistor and the fifth field effect transistors are short-circuited, whose gate electrode is supplied with a negative-phase signal of the second signal, and whose drain electrode outputs a positive-phase signal of the output signal.
